(19) United States
(12) Patent Application Publication
(10) Pub. No.: US 2025/0072006 A1
(43) Pub. Date: Feb. 27, 2025

(54) HIGH-SPEED AND HIGH-ENERGY-EFFICIENCY MAGNETIC TUNNEL JUNCTION DEVICE

(71) Applicant: INDUSTRY-UNIVERSITY COOPERATION FOUNDATION HANYANG UNIVERSITY ERICA CAMPUS, Ansan-si (KR)

(72) Inventors: Saeroonter OH, Seoul (KR); Stanislav SIN, Ansan-si (KR)

(73) Assignee: INDUSTRY-UNIVERSITY COOPERATION FOUNDATION HANYANG UNIVERSITY ERICA CAMPUS, Ansan-si (KR)

(21) Appl. No.: 18/944,903

(22) Filed: Nov. 12, 2024

Related U.S. Application Data
(63) Continuation of application No. PCT/KR2023/009455, filed on Jul. 5, 2023.

(30) Foreign Application Priority Data
Jul. 5, 2022 (KR) 10-2022-0082429

(51) Int. Cl. H10B 61/00

(52) U.S. Cl. CPC H10B 61/20

(57) ABSTRACT

Disclosed herein is a high-speed and high-energy-efficiency magnetic tunnel junction (MTJ) device. The high-speed and high-energy-efficiency MTJ device includes a main pinned layer whose magnetization direction is determined to be a first direction, an auxiliary pinned layer which is insulated from the main pinned layer by an insulator (insulating material) and whose magnetization direction is determined to be a second direction orthogonal to the first direction, an oxide barrier layer stacked on the main pinned layer and the auxiliary pinned layer, and a free layer stacked on the oxide barrier layer and having stable magnetization states parallel and antiparallel to the magnetization direction of the main pinned layer. According to the present disclosure, a novel three-terminal MTJ device with an auxiliary ferromagnet that is perpendicular to magnetization of a free layer may be provided.

### CROSS-REFERENCE TO RELATED APPLICATION

This application is a continuation of pending PCT International Application No. PCT/KR2023/009455, which was filed on Jul. 5, 2023, and which claims priority to and the benefit of Korean Patent Application No. 10-2022-0082429, which was filed in the Korean Intellectual Property Office on Jul. 5, 2022, the disclosure of which is incorporated herein by reference in its entirety.

### BACKGROUND

### 1. Field of the Invention

The present disclosure relates to a high-speed and high-energy-efficiency magnetic tunnel junction (MTJ) device, and more particularly, to a high-speed, high-energy-efficiency MTJ device including an auxiliary pinned magnetization layer.

### 2. Discussion of Related Art

Among nonvolatile memory candidates, a magnetoresistive random access memory (MRAM) has relatively low switching delay and low energy. After 20 years of extensive research, a magnetic tunnel junction (MTJ) MRAM has been successfully commercialized.

A conventional MTJ includes an oxide barrier layer between two ferromagnetic layers (a free layer (FL) and a pinned layer (PL)). The resistance of the device is determined by magnetization directions of the FL and the PL. The FL may have two directions including a parallel direction and an antiparallel direction to the magnetization direction of the PL. The resistance of the MTJ is high when the FL is in an antiparallel state and is low when the FL is in a parallel state. Magnetic switching is performed by a current flowing into a device. The current applies a spin-transfer torque (STT) to the FL to change the magnetization direction of the FL. The magnetization direction or resistance is changed depending on the direction of current to implement memory values of 0 and 1.

The switching power and delay of the MRAM are still about 10 times higher than those of a static RAM (SRAM). This is because of a low STT when the magnetization is collinear to incoming spin. That is, in the conventional device, switching occurs due to the current, and since the STT is small in an initial stage of changing the magnetization direction of the FL, the switching of the magnetization direction is largely dependent on random thermal fluctuation of the FL magnetization (thermally assisted switching). Therefore, it is reported to have the following disadvantages: a long switching delay, high energy consumption, and stochastic switching behavior. In order to address these problems, several novel spintronic devices have been proposed, such as spin-orbit torque devices, MTJ devices with perpendicular polarizers, and MTJ devices with complementary polarizers. However, the performance improvements resulting from these proposals are quite minimal. The spin-orbit torque device typically has an in-plane magnetization direction, resulting in low thermal stability, and a switching time of the device with the perpendicular polarizer has a nanosecond order at a current density of 4×10⁹ A/m². The MTJ device with a complementary polarizer has two antiparallel PLs, and a current path is determined according to the magnetization direction of the FL so that switching of the magnetization direction may occur from the antiparallel state to reduce the switching time and power, but a torque is low because an initial magnetization direction of the FL is also collinear.

### SUMMARY

The present disclosure is directed to providing a novel three-terminal magnetic tunnel junction (MTJ) device with an auxiliary ferromagnet that is capable of solving the above problems of the conventional device technology.

According to an aspect of the present disclosure, there is provided a high-speed and high-energy-efficiency MTJ device including a main pinned layer whose magnetization direction is determined to be a first direction, an auxiliary pinned layer which is insulated from the main pinned layer by an insulator (insulating material) and whose magnetization direction is determined to be a second direction (which is orthogonal to the first direction), an oxide barrier layer stacked on the main pinned layer and the auxiliary pinned layer, and a free layer stacked on the oxide barrier layer and having stable magnetization states parallel or antiparallel to the magnetization direction of the main pinned layer.

The oxide barrier layer may be tunneling barrier, may prevent the main pinned layer and the auxiliary pinned layer from being directly in contact with the free layer, and may be made of a material such as magnesium oxide or aluminum oxide.

The high-speed and high-energy-efficiency MTJ device may further include a first terminal configured to input an externally applied voltage pulse into the main pinned layer, a second terminal configured to input an externally applied voltage pulse into the auxiliary pinned layer, and a third terminal configured to input an externally applied voltage pulse into the free layer.

The magnetization direction of the free layer may be partially shifted by a first electrical pulse passing through the second terminal and the third terminal, and after the initial shifting, switching of the magnetization direction of the free layer may be completed by a second electrical pulse passing through the first terminal and the third terminal.

The first direction may be an out-of-plane direction, and the second direction may be an in-plane direction and is orthogonal to the first direction.

A second spin transfer torque, which is generated when a voltage is applied between the first terminal and the third terminal, may be applied to the free layer whose magnetization direction is previously shifted due to a first spin transfer torque generated when a voltage is applied between the second terminal and the third terminal so that the magnetization direction of the free layer may become an up or down direction.

The second spin transfer torque, which is generated by a current flowing from the first terminal to the third terminal when a voltage is applied between them, may be applied to the free layer whose magnetization direction is previously shifted due to a first spin transfer torque generated when a voltage is applied between the second terminal and the third terminal so that the magnetization direction of the free layer may become an up direction.

The second spin transfer torque, which is generated by a current flowing from the third terminal to the first terminal when a voltage is applied between the first terminal and the third terminal, may be applied to the free layer whose magnetization direction is previously shifted due to a first spin transfer torque generated when a voltage is applied between the second terminal and the third terminal so that the magnetization direction of the free layer may become a down direction.

The magnetization direction of the auxiliary pinned layer may be an in-plane direction lying in the flat surface of a thin film, and the magnetization direction of the main pinned layer may be perpendicular to the flat surface of the thin film.

The voltage applied between the second terminal and the third terminal, and the voltage applied between the first terminal and the third terminal may be supplied from different power sources.

According to another aspect of the present disclosure, there is provided a high-speed and high-energy-efficiency MTJ device including a first layer including a main pinned region in which a magnetization direction is determined to be a first direction, an auxiliary region in which a magnetization direction is determined to be a second direction orthogonal to the first direction, and an insulating region between the main pinned region and the auxiliary region; an intermediate layer stacked on the first layer and including an oxide barrier; and a second layer stacked on the intermediate layer and including a free region with stable magnetization states parallel or antiparallel to the first direction.

Areas occupied by the main fixed region and the auxiliary region may be 20% and 70% of the total area of the first layer, respectively.

According to still another aspect of the present disclosure, there is provided a method of operating a high-speed and high-energy-efficiency MTJ device, which includes sequentially applying a voltage to combinations of two terminals among a first terminal connected to a main pinned layer whose magnetization direction is determined to be a first direction, a second terminal connected to an auxiliary pinned layer whose magnetization direction is determined to be a direction orthogonal to the first direction, and a third terminal connected to a free layer having stable magnetization states parallel and antiparallel to the magnetization direction of the main pinned layer; applying a voltage to a combination of the second terminal and the third terminal and shifting the magnetization direction of the free layer; and applying a voltage to a combination of the first terminal and the third terminal and completing switching of the magnetization direction of the free layer.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a diagram illustrating a configuration of a high-speed and high-energy-efficiency magnetic tunnel junction (MTJ) device according to an embodiment of the present disclosure;

FIG. 2 is a diagram illustrating a current profile for switching the device according to an embodiment of the present disclosure;

FIG. 3 is a diagram illustrating a current profile for switching the device without delay between the first and second current pulses;

FIGS. 4A to 4F show graphs showing switching time distributions in conventional devices with different switching currents, wherein FIGS. 4A to 4C show transitions of parallel (P)→antiparallel (AP) and FIGS. 4D to 4F show transitions of AP→P;

FIGS. 5A to 5F show graphs showing switching time distributions in proposed devices with different switching currents, wherein FIGS. 5A to 5C show transitions of P→AP and FIGS. 5D to 5F show transitions of AP→P;

FIGS. 6A and 6B are a diagram illustrating results of cumulative switching probabilities of the conventional devices, wherein FIG. 6A shows a switching probability of P→AP over time, and FIG. 6B shows a switching probability of AP→P;

FIGS. 7A and 7B are a diagram illustrating results of cumulative switching probabilities of proposed devices, wherein FIG. 7A shows a switching probability of P→AP over time, and FIG. 7B shows a switching probability of AP→P;

FIG. 8 is a diagram illustrating a comparison of the dependence of a mean switching time with respect to a switching current in the conventional device and the proposed device;

FIG. 9 is a diagram illustrating a comparison of the relationship between mean joule loss and the switching current in the conventional device and the proposed device;

FIG. 10 is a diagram illustrating a comparison of the relationship between a mean energy-delay product and the switching current in the conventional device and the proposed device;

FIG. 11 is a schematic diagram illustrating a parallel mode operation for a three-terminal device according to an embodiment of the present disclosure;

FIG. 12 is a schematic diagram illustrating a mode operation with no delay for the three-terminal device according to an embodiment of the present disclosure; and

FIGS. 13A and 13B are a schematic diagram illustrating a spin injection mechanism of the three-terminal device according to an embodiment of the present disclosure.

### DETAILED DESCRIPTION OF EXEMPLARY EMBODIMENTS

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined by only the scope of the appended claims. The same reference numerals refer to the same components throughout the present specification.

Terms used herein are for the purpose of describing the embodiments and are not intended to limit the present disclosure. In the present specification, the singular forms include the plural forms unless the context clearly dictates otherwise. It is noted that the terms “comprise” and/or “comprising” used herein does not exclude the presence or addition of one or more other components, steps, operations, and/or elements in addition to stated components, steps, operations, and/or elements.

Further, the embodiments described herein will be described with reference to cross-sectional views and/or plan views, which are ideal exemplary diagrams of the present disclosure. In the drawings, thicknesses of films and regions are exaggerated to effectively describe the technical content. Therefore, the shape of an exemplary diagram may be modified by manufacturing techniques and/or tolerances. Accordingly, the embodiments of the present disclosure are not limited to specific shapes shown in the drawings, and include alternations in the shape that is produced according to the manufacturing process. For example, etching regions shown in the drawings at a right angle may be rounded or may have a shape with a certain curvature. Thus, illustrative regions in the drawings have schematic attributes, and the shapes of the illustrative regions in the drawings are intended to illustrate specific shapes of regions of devices and not intended to limit the scope of the present disclosure.

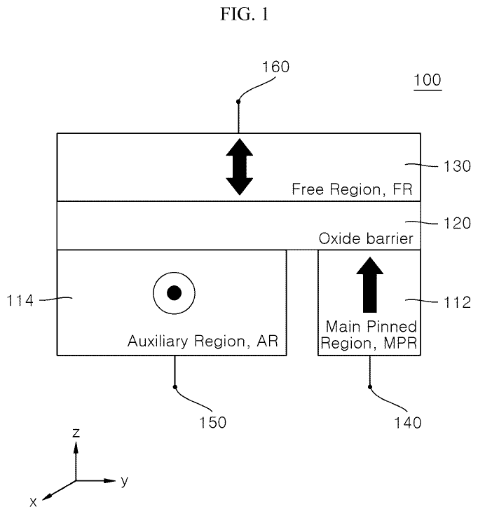

FIG. 1 is a diagram illustrating a configuration of a high-speed and high-energy-efficiency magnetic tunnel junction (MTJ) device according to an embodiment of the present disclosure. As shown in FIG. 1, a high-speed and high-energy-efficiency MTJ device 100 (hereinafter, simply referred to as an “MTJ device”) includes a main pinned layer 112, an auxiliary pinned layer 114, an oxide barrier layer 120, a free layer 130, a first terminal 140, a second terminal 150, and a third terminal 160.

The main pinned layer 112 and the auxiliary pinned layer 114 may be disposed on the same layer with a space filled with an insulator for preventing a short circuit therebetween. This is referred to as a bottom layer. The oxide barrier layer 120 may be disposed on the bottom layer. This is referred to as an middle layer. In addition, the free layer 130 may be placed on the middle layer. This is referred to as a top layer.

The main pinned layer 112 may be a crystalline layer. The main pinned layer 112 may be a ferromagnetic layer. The main pinned layer 112 may have a fixed magnetization direction. For example, a magnetization direction of the main pinned layer 112 may be a vertical direction (z-direction). That is, the magnetization direction of the main pinned layer 112 may be in an out-of-plane (OOP) direction. The main pinned layer 112 may include at least one of cobalt (Co), nickel (Ni), and iron (Fe). For example, the main pinned layer 112 may include cobalt nickel (CoNi), cobalt iron boride (CoFeB), cobalt chromium (CoCr), cobalt iron (CoFe), cobalt platinum (CoPt), iron platinum (FePt), iron boride (FeB), cobalt boride (CoB), cobalt iron aluminum (CeFeAl), or a combination thereof.

The auxiliary pinned layer 114 may be a crystalline layer. The auxiliary pinned layer 114 may be a ferromagnetic layer. The auxiliary pinned layer 114 may have a fixed magnetization direction. However, the magnetization direction of the auxiliary pinned layer 114 may non-collinear to the magnetization direction of the main pinned layer 112. Preferably, the magnetization direction of the auxiliary pinned layer 114 may be orthogonal to the magnetization direction of the main pinned layer 112. For example, the magnetization direction of the main pinned layer 112 may be the vertical direction (z-direction), whereas the magnetization direction of the auxiliary pinned layer 114 may be a direction (x-direction) orthogonal to the vertical direction. That is, the magnetization direction of the auxiliary pinned layer 114 may be an in-plane (IP) direction. The auxiliary pinned layer 114 may include at least one of Co, Ni, and Fe. For example, the auxiliary pinned layer 114 may CoNi, CoFeB, CoCr, CoFe, CoPt, FePt, FeB, CoB, CeFeAl, or a combination thereof.

The different magnetization directions of the main pinned layer 112 and the auxiliary pinned layer 114 may be achieved by different heat treatments or different layer thicknesses. For example, when FePt is deposited at a temperature of 27° C., an in-plane magnetization direction is obtained, and when FePt is deposited at a temperature of 300° C. and annealed at a temperature of 500° C., an out-of-plane magnetization direction is obtained. In the case of a material with interfacial anisotropy, an out-of-plane magnetization direction is obtained when a layer thickness is thin, and an in-plane magnetization direction is obtained when the layer thickness is thick.

An insulator insulating the main pinned layer 112 for the auxiliary pinned layer 114 may include, for example, silicon oxide (SiO₂), silicon nitride (SiN), or a combination thereof.

As shown in the drawing, the main pinned layer 112, the auxiliary pinned layer 114, and the insulator may all be disposed on the same layer (i.e., the bottom layer). From this point of view, the bottom layer may be regarded as including the main pinned layer 112 and the auxiliary pinned layer 114 and including a main pinned region (MPR), an auxiliary region (AR), and an insulating region, which correspond to the insulator. Alternatively, the present disclosure is not necessarily limited thereto, and in some embodiments, positions at which the main pinned layer and the auxiliary pinned layer are disposed may be swapped, or the main pinned layer and the auxiliary pinned layer may be disposed in different layers as long as they are distinguishable by the insulator. However, arranging the main pinned layer and the auxiliary pinned layer on the same layer is advantageous in increasing the degree of integration.

The oxide barrier layer 120 may be a crystalline or amorphous layer. The oxide barrier layer 120 may be a nonmagnetic or magnetic layer. The oxide barrier layer 120 may separate the main pinned layer 112 and the auxiliary pinned layer 114 from the free layer 130. The oxide barrier layer 120 may include aluminum oxide (Al₂O₃), magnesium oxide (MgO), magnesium aluminum oxide (MgAlO), hafnium oxide (HfO₂), zirconium oxide (ZrO₂), zinc oxide (ZnO₂), titanium oxide (TiO₂), or a combination thereof. In some embodiments, the oxide barrier layer 120 may include a plurality of layers. For example, the oxide barrier layer 120 may have a stacked structure such as Mg/MgO, MgO/Mg, MgO/MgAlO, MgAlO/MgO, Mg/MgAlO/Mg, MgO/MgAlO/MgO, or MgAlO/MgO/MgAlO.

The free layer 130 may be a ferromagnetic layer. The magnetization direction of the free layer 130 may be changed to the vertical direction (+z-direction) or a direction (−z-direction) opposite to the vertical direction. The free layer 130 may have a magnetization direction parallel or antiparallel to the magnetization direction of the main pinned layer 112. That is, the free layer 130 may have an out-of-plane (OOP) direction. The free layer 130 may be a crystalline layer. The free layer 130 may include Co, Fe, cobalt boride (CoB), iron boride (FeB), cobalt iron (CoFe), cobalt iron boride (CoFeB), cobalt oxide (CoO), iron oxide (FeO), cobalt iron oxide (CoFeO), or a combination thereof.

In this way, the MTJ device 100 may be a three-terminal device and may be regarded as being formed of three ferromagnetic layers and one oxide barrier.

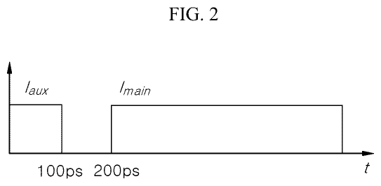

The MTJ device 100 may be switched using two consecutive pulses. A short electrical (current) pulse is transmitted to the auxiliary pinned layer as a first pulse to shift the magnetization direction of the free layer, and a second pulse is transmitted to the main pinned layer to complete switching. FIG. 2 shows a current profile for switching the device according to an embodiment of the present disclosure. As shown in FIG. 2, the first pulse may have a duration of 100 ps and a delay before the second pulse may be 100 ps.

More specifically, the first pulse is relatively short, is transmitted from the auxiliary pinned layer 114 toward the free layer 130 by a voltage applied between the second terminal 150 and the third terminal 160, and changes the magnetization direction of the free layer 130. In this case, since the angle between the magnetization directions of the auxiliary pinned layer 114 and the free layer 130 is 90 degrees, a strength of a spin-transfer torque (STT) is greatly improved. The STT becomes maximum. This reduces a switching delay (delay time) and power consumption. The second pulse is transmitted from the main pinned layer 112 to the free layer 130 by a voltage applied between the first terminal 140 and the third terminal 160 to complete the magnetization direction switching. Meanwhile, a resistance sensing (read) operation of the junction is possible by transmitting a current to the main pinned layer 112 and the free layer 130.

According to the embodiment of the present disclosure, the switching time, switching current, power consumption, and energy-delay-product are all significantly reduced. Since a random thermal fluctuation does not rely on random fluctuations compared to the related art, a low-temperature operation is possible and switching time non-uniformity is reduced.

### Embodiment

A lower layer of the device 100 according to an embodiment of the present disclosure includes two fixed ferromagnetic regions. A first region has out-of-plane magnetization (along a z-axis) and is referred to as an MPR. A second region is referred to as an AR and has in-plane magnetization (along an x-axis). An oxide barrier constitutes an intermediate layer. A free region (FR) may be grown on the oxide barrier. The free region (FR) has switchable out-of-plane magnetization.

The device 100 uses an STT for magnetization switching in the FR. The magnetization dynamics may be described by the well-known Landau-Lifshitz-Gilbert (LLG) equation.

$$\frac{d m}{dt} {( 1 + α )}^{2} = - {γ}_{0} \qquad [ Equation 1 ]$$

$$[ m \times ( {H}_{eff} + {H}_{th} + α {T}_{s} ) + m \times ( m \times ( {H}_{eff} + {H}_{th} ) ) + {T}_{s} ]$$

Here, m denotes a unit vector of magnetization, α denotes a phenomenological damping constant, γ₀ denotes a gyromagnetic ratio, H_{eff} denotes an effective magnetic field due to different contributions, Hₜₕ denotes a random thermal field, and Tₛ denotes an STT term.

The STT term is as follows:

$${T}_{s} = \frac{hJ ε}{2 q {μ}_{0} {M}_{s} d} ( m \times ( {m}_{p} \times m ) ) \qquad [ Equation 2 ]$$

Here, h denotes a reduced Planck's constant, J denotes a current density, ε denotes an asymmetry term, q denotes an elementary charge, μ₀ denotes a permittivity of vacuum, Mₛ denotes a saturation magnetization, d denotes a thickness of an FR, and mₚ denotes a magnetization of a pinned region (PR).

In Equation 2, it can be seen that the STT is proportional to a magnetization vector product of the FR and the PR. Therefore, the STT disappears when an angle between m and mₚ is θ={0, π}. In addition, the STT is maximized near θ=π/2. However, due to the asymmetric term ε, a maximum torque shifts slightly in an antiparallel state at θ>π/2. Switching of the conventional MTJ relies heavily on random thermal fluctuations of the magnetization vector. This switching is referred to as thermally assisted switching and a high current density should be applied for a long period of time. When m is collinear with mₚ, much energy should be dissipated before the magnetization even barely begins to move.

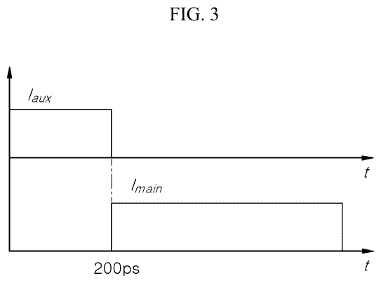

The device according to the embodiment of the present disclosure may be switched by two consecutive current pulses shown in FIG. 3. A first pulse Iₐᵤₓ is applied from an AR to the FR. Due to the STT, the magnetization shifts along the x-axis. This is because a torque applied at the initial θ=π/2 is relatively large. Therefore, the current is utilized more efficiently. A second pulse Iₘₐᵢₙ is applied from the MPR to the FR as soon as the first pulse ends. The magnetization is oriented in the ±z directions.

In order to verify validity of the device, LLG simulations were performed on the conventional device and the device according to the embodiment of the present disclosure in MATLAB. Simulation parameters are enumerated in the following Table 1.

TABLE 1

| Parameter | Value | |
|---|---|---|
| Gₚ | 2.85 * 10⁻³ | S |
| Gₐₚ | 1.23 * 10⁻³ | S |
| Hₖ | 7957.5 | A/m |
| α | 0.007 | |
| M_{eff} | 8 * 10⁵ | A/m |
| M_{S} | 5 * 10⁵ | A/m |

| V_{FL} | 300 nm × 95 nm × 2 nm |
|---|---|
| P_{PL} | 0.75 |
| P_{FL} | 0.75 |
| Λ_{PL} | 1.90 |
| Λ_{FL} | 1.10 |

As shown in Table 1, it can be summarized that an area is 300 nm×95 nm, thicknesses of the FL, the barrier, and a main pinned layer (MPL) (=AL) are 2 nm, 2 nm, and 20 nm, respectively, an area of the AL is 70% of the total area, an area of the MPL is 20%, and the remaining 10% gap is an insulator.

For comparison with the proposed device, the conventional device that had a first layer of a fixed region without an AR, a second layer of an oxide barrier, and a third layer of an FR was used, and only two terminals for applying voltage to the fixed region and the free region were used.

Magnetization of the FR was expressed using macrospin approximation. For simplicity, it was assumed that Iₐᵤₓ=Iₘₐᵢₙ and a duration of the first pulse was 200 ps. The second pulse continues until the device is completely switched. Aspect ratios of the MPR and the AR may be changed. Generally, when the area increases, resistance of the MTJ device decreases. However, this also reduces a current density. Therefore, the STT decreases with the area. Since the initial pulse Iₐᵤₓ is relatively short, it is reasonable to form the area of the MPR to be small in order to increase the STT. The areas of the MPR and the AR were assumed to be 20% and 70% of the total area, respectively. The remaining 10% gap was filled with an insulator to prevent a short circuit. Resistance of the MTJ was calculated as follows.

$$R = {G}^{- 1} = {[ {G}_{P} {cos}^{2} \frac{θ}{2} + {G}_{ap} {sin}^{2} \frac{θ}{2} ]}^{- 1} \qquad [ Equation 3 ]$$

Here, θ denotes an angle between m and mₚ. Gₚ and Gₐₚ are conductances of a parallel state (P) and an antiparallel state (AP), respectively.

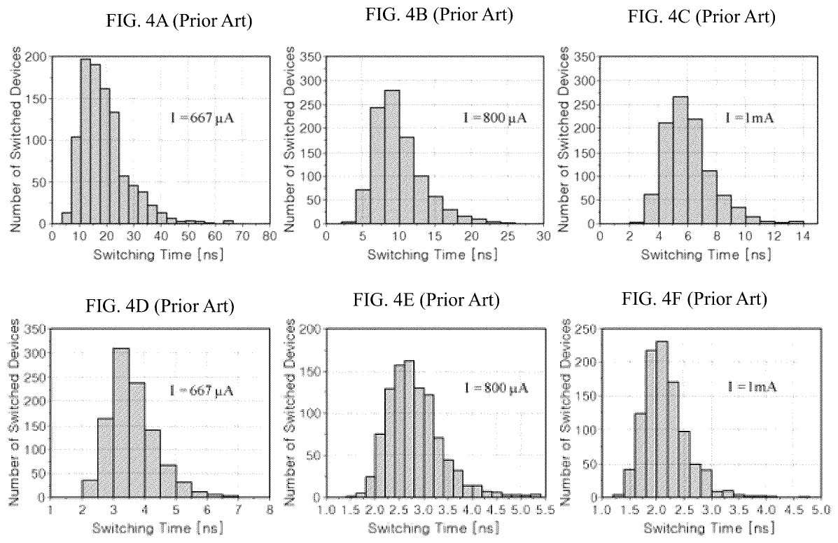

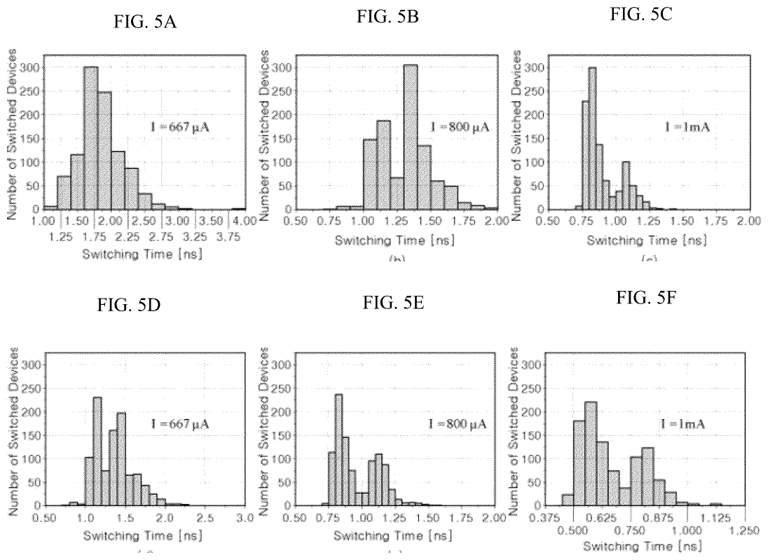

Since the switching of the MTJ is a probabilistic process, 1000 simulations were performed on different current values. The first current pulse and the second current pulse have the same amplitude. The simulation performance results are shown in FIGS. 4A to 5F. FIGS. 4A to 4F show graphs showing switching time distributions in conventional devices with different switching currents, wherein FIGS. 4A to 4C show transitions of P→AP and FIGS. 4D to 4F show transitions of AP→P. FIGS. 5A to 5F show graphs showing switching time distributions in proposed devices with different switching currents, wherein FIGS. 5A to 5C show transitions of P→AP and FIGS. 5D to 5F show transitions of AP→P.

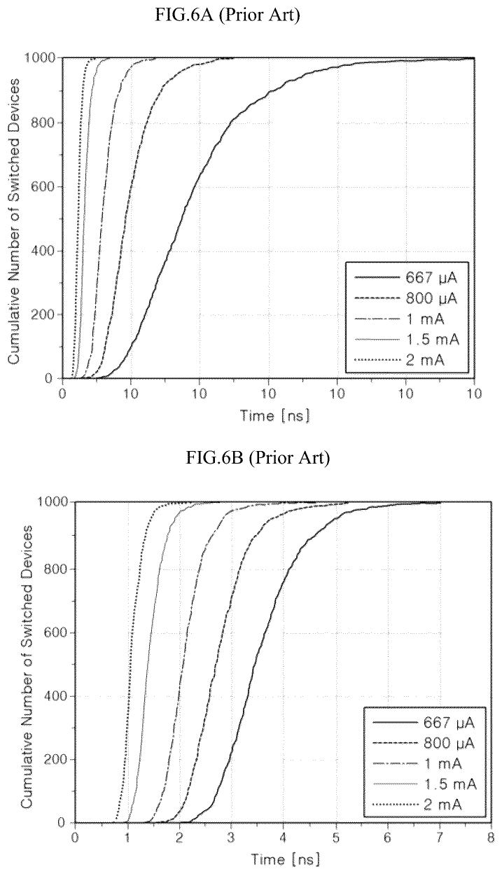

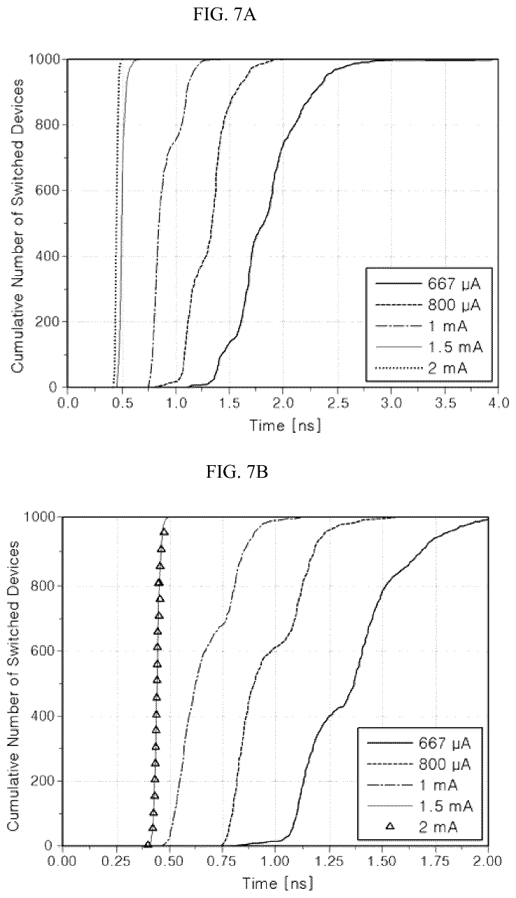

The results comparing cumulative switching probabilities between the conventional device and the proposed device are shown in FIGS. 6A, 6B, 7A and 7B. FIG. 6A shows a switching probability of P→AP over time in the conventional two-terminal device. Within tens of nanoseconds, 100% of the devices were switched. FIG. 7A shows the same plot for a three-terminal device according to the embodiment of the present disclosure. A switching time was about a few nanoseconds at a lower current and a switching time was about hundreds of picoseconds at a higher current. FIGS. 6B and 7B show AP→P switching probabilities for the conventional device and the proposed device, respectively. The conventional device achieved nanosecond switching, whereas the proposed device exhibited sub-nanosecond switching at 1 ns. As shown in the drawings, the proposed device has a shorter mean switching time and a steeper probability distribution. In addition, it can be concluded that there is saturation in the switching delay at a higher current.

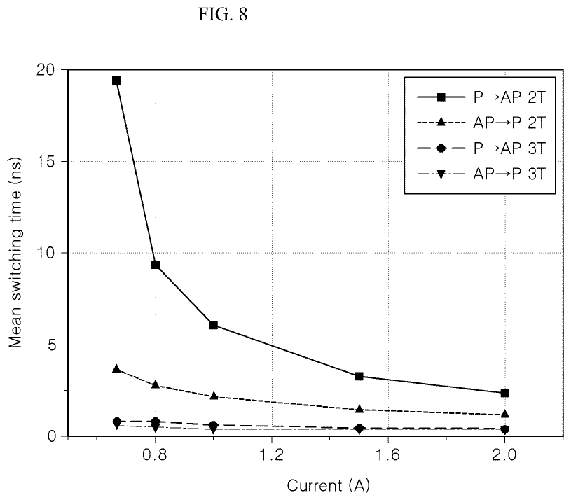

Dependence of a mean switching time on the switching current is shown in FIG. 8. P→AP and AP→P correspond to parallel-antiparallel switching and antiparallel-parallel switching, respectively. The conventional two-terminal MTJ device is denoted as 2T, and the proposed device is denoted as 3T. A mean switching time of the conventional device was about a few nanoseconds. Meanwhile, a mean switching time of the proposed device achieved a sub-nanosecond limit. It is clear from the drawings that the proposed device is about ten times faster. Faster switching of the conventional device could be achieved by increasing the current, but energy was additionally consumed. Even at a current of 2 mA, the proposed device is 5.73 times faster in the P→AP switching and 3.12 times faster in the AP→P switching.

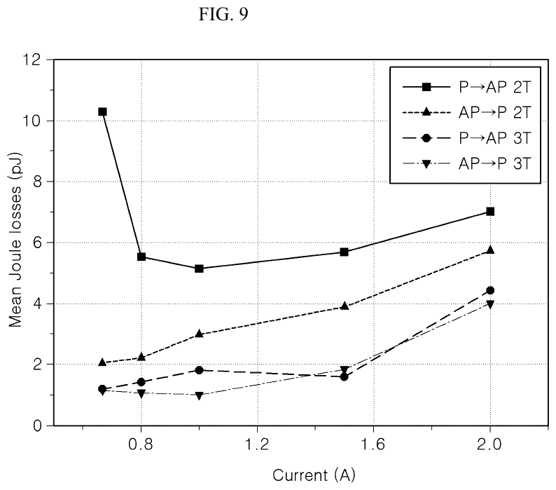

In a loss calculation, two energy terms including magnetic energy and energy due to Joule heating were considered. Magnetic loss is about 10-27 J, whereas Joule loss is about 10-12. Therefore, the magnetic energy is omitted. The mean Joule losses versus switching current are shown in FIG. 9. The conventional device shows energy consumption of 5.14 pJ at a current of 1 mA for the P→AP switching and the lowest energy consumption of 2.06 pJ at a current 667 μA for the AP→P switching. The proposed device shows energy consumption of 1.18 pJ at the current of 667 μA for the P→AP switching and the lowest energy consumption of 1.00 pJ at the current of 1 mA for the AP→P switching. This significantly improved energy consumption is mainly due to the faster switching. A current value that is greater than 1 mA resulted in performance degradation. This is because the switching delay decreases more slowly than that of an I²R product.

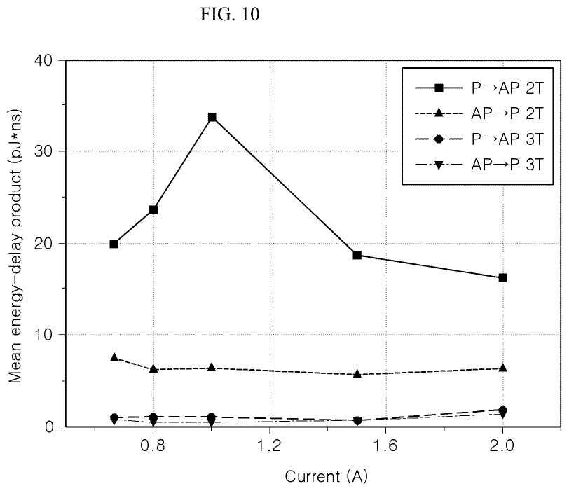

A mean energy-delay product comparison is shown in FIG. 10. The best results of the conventional device were 16.23 pJ·ns and 5.69 pJ·ns for the P→AP switching and the AP→P switching, respectively. The best results of the proposed device were 0.96 pJ·ns and 0.42 pJ·ns. Therefore, the performance was improved by factors of 16.91 and 13.55. Due to saturation of the switching delay, the energy-delay product also exhibits a local minimum and then increases.

The following tables summarize the above simulation results.

TABLE 2

| | | Conventional device (P→AP) | | | | Proposed device (P→AP) | | | |
|---|---|---|---|---|---|---|---|---|---|
| I | | <t_{sw}> | <E_{mag}> | <Eⱼₒᵤₗₑ> | <Et> | <t_{sw}> | <E_{mag}> | <Eⱼₒᵤₗₑ> | <Et> |
| 667 | μA | 1.94e−8 | 6.04e−27 | 1.03e−11 | 2.00e−20 | 1.85e−9 | 5.68e−28 | 1.13e−12 | 2.09e−21 |
| 800 | μA | 9.31e−9 | 2.41e−27 | 5.54e−12 | 23.65e−21 | 1.31e−9 | 3.34e−28 | 9.59e−13 | 12.56e−22 |
| 1 | mA | 6.08e−9 | 1.46e−27 | 5.14e−12 | 33.68e−21 | 8.97e−10 | 2.71e−28 | 1.13e−12 | 10.14e−22 |
| 1.5 | mA | 3.29e−9 | 6.92e−28 | 5.69e−12 | 18.72e−21 | 5.03e−10 | 1.23e−28 | 1.40e−12 | 7.04e−22 |
| 2 | mA | 2.31e−9 | 5.17e−28 | 7.03e−12 | 16.24e−21 | 4.49e−10 | 1.34e−28 | 2.14e−12 | 9.61e−22 |

TABLE 3

| | | Conventional device (AP→P) | | | | Proposed device (AP→P) | | | |
|---|---|---|---|---|---|---|---|---|---|
| I | | <t_{sw}> | <E_{mag}> | <Eⱼₒᵤₗₑ> | <Et> | <t_{sw}> | <E_{mag}> | <Eⱼₒᵤₗₑ> | <Et> |
| 667 | μA | 3.62e−9 | 8.46e−28 | 2.06e−12 | 7.60e−21 | 1.36e−9 | 4.03e−28 | 7.11e−13 | 9.67e−22 |
| 800 | μA | 2.81e−9 | 6.67e−28 | 2.23e−12 | 6.26e−21 | 9.65e−10 | 2.97e−28 | 7.26e−13 | 70.06e−23 |
| 1 | mA | 2.15e−9 | 6.81e−28 | 2.97e−12 | 6.39e−21 | 6.69e−10 | 2.41e−28 | 8.21e−13 | 54.92e−23 |
| 1.5 | mA | 1.46e−9 | 4.11e−28 | 3.90e−12 | 5.69e−21 | 4.41e−10 | 1.04e−28 | 9.34e−13 | 41.19e−23 |
| 2 | mA | 1.12e−9 | 4.31e−28 | 5.73e−12 | 6.42e−21 | 4.44e−10 | 1.37e−28 | 1.70e−12 | 7.55e−22 |

In Tables 2 and 3 above, I denotes the switching current, (t_{sw}) denotes the switching time, (E_{mag}) denotes mean magnetic losses, (Eⱼₒᵤₗₑ) denotes the mean joule loss, and (Eₜ) denotes a value related to the mean energy-delay product.

As described above, the present disclosure proposes the three-terminal MTJ device with the auxiliary pinned layer. When the MTJ is in a parallel state, the STT is small enough to be ignored. Since the AR has an in-plane magnetization, a current pulse through the AR may easily shift the magnetization of the FL. The simulation results show that the mean energy-delay product can be reduced by factors of 16.91 and 13.55 for the P→AP switching and the AP→P switching, respectively.

Since the MTJ device according to the embodiment of the present disclosure has the main pinned magnetization layer and the auxiliary pinned magnetization layer, the MTJ device has a structure in which two MTJs are present in one device. The main pinned magnetization layer may be regarded as a first MTJ and the auxiliary pinned magnetization layer may be regarded as a second MTJ. The first and second MTJs may be disposed on one layer that is a first layer. Accordingly, the device according to the embodiment of the present disclosure shows a significant difference in horizontal and vertical layout from the conventional device. In the present disclosure, it can be considered that two MTJs are present on one layer. That is, compared to the conventional device, the device of the present disclosure may have a layout that is relatively longer in width.

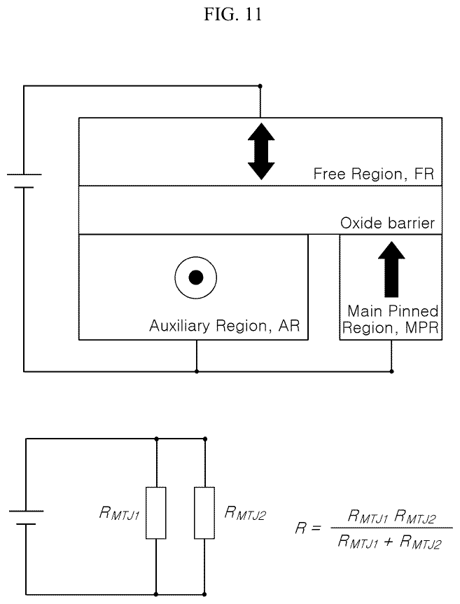

In addition, a three-terminal structure is applied to the MTJ device according to the embodiment of the present disclosure, the MTJ device may be interpreted as a parallel mode operation in terms of a circuit. The three-terminal structure is shown in FIG. 11. Compared to the conventional device to which the two-terminal structure is applied, the three-terminal structure may have an advantage of reducing resistance of a current passing through the MTJs. In the two-terminal structure, even when two MTJs are disposed as in the present disclosure, since R_{MTJ1} and R_{MTJ2} are inevitably disposed in series, resistance (R=R_{MTJ1}+R_{MTJ2}) is formed to be greater than resistance of the present disclosure (R=(R_{MTJ1}R_{MTJ2})/(R_{MTJ1}+R_{MTJ2})).

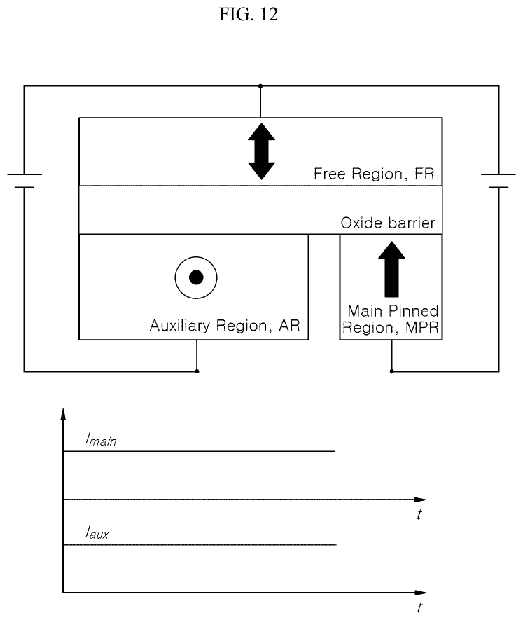

The benefits of applying the three-terminal structure may also be considered in terms of a clock timing (see FIG. 12). This may be referred to as a no-delay mode operation. When a circuit is configured with two power supplies as shown in FIG. 12 for switching with two pulses, two pulses Iₘₐᵢₙ and Iₐᵤₓ may be turned on simultaneously, which enables simpler clock timing control. That is, no-delay clocking is possible.

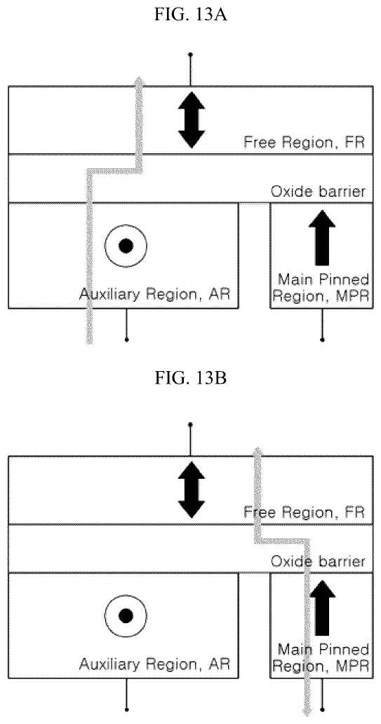

In addition, in the MTJ device according to the embodiment of the present disclosure, a spin current is directly injected from the auxiliary pinned layer to the FL. The MTJ device is driven by an electric field (tunneling current) (see FIGS. 13A and 13B). When a different method other than the method of directly injecting a charge current is used, in some cases, spin diffusion may occur in an interface between layers (for example, an interface between the FL and another layer disposed above or below the FL). This enables electrons of opposite polarity to be accumulated on a side opposite to the interface, and thus it is somewhat less efficient and implies a probability of occurrence of undesirable spin diffusion. One scenario is that most of the spin electrons are accumulated on one side of the device to generate a spin potential difference, causing spin diffusion to the opposite side. Most spins flow on one side and a minority of spins flow on an opposite side. Accordingly, the present disclosure employs a mechanism for directly injecting electrons into the FL as a spin injection mechanism. In this way, by directly injecting the spin current into the FL, the generation of an undesirable spin current can be prevented.

The proposed device can be applied to a high-speed and high-density MRAM or a spin logic application, and the magnetoresistive memory device of each embodiment of the present disclosure can be used as memories included in electronic products such as mobile devices, memory cards, and computers.

According to the present disclosure, a novel three-terminal MTJ device with an auxiliary ferromagnet that is perpendicular to magnetization of a free layer can be provided.

In addition, according to the present disclosure, a high-speed and high-energy-efficiency MTJ device that can significantly reduce a switching time, a switching current, power consumption, and an energy-delay-product by greatly increasing spin-transfer torques (STTs) in parallel/antiparallel states can be provided.

In addition, according to the present disclosure, since a random thermal fluctuation is not assisted by heat compared to the related art, a low-temperature operation can be possible and switching time non-uniformity can be reduced.

Although the technical spirit of the present disclosure has been specifically described in accordance with the above exemplary embodiments, it should be noted that the above embodiments are for illustrative purposes only and not for limitation thereof. In addition, those skilled in the art will appreciate that various embodiments are possible within the scope of the technical spirit of the present disclosure.

What is claimed is:

1. A high-speed and high-energy-efficiency magnetic tunnel junction (MTJ) device comprising:
a main pinned layer whose magnetization direction is determined to be a first direction;
an auxiliary pinned layer which is insulated from the main pinned layer by an insulator and whose magnetization direction is determined to be a second direction orthogonal to the first direction;
an oxide barrier layer stacked on the main pinned layer and the auxiliary pinned layer; and
a free layer stacked on the oxide barrier layer and having stable magnetization states parallel and antiparallel to the magnetization direction of the main pinned layer.

2. The high-speed and high-energy-efficiency MTJ device of claim 1, further comprising:
a first terminal configured to input an externally applied voltage pulse into the main pinned layer;
a second terminal configured to input an externally applied voltage pulse into the auxiliary pinned layer; and
a third terminal configured to input an externally applied voltage pulse into the free layer.

3. The high-speed and high-energy-efficiency MTJ device of claim 2, wherein:
the magnetization direction of the free layer is shifted by a first electrical pulse passing through the second terminal and the third terminal; and
after the shifting, switching of the magnetization direction of the free layer is completed by a second electrical pulse passing through the first terminal and the third terminal.

4. The high-speed and high-energy-efficiency MTJ device of claim 1, wherein:
the first direction is an out-of-plane direction and the second direction is an in-plane direction; and
the second direction is perpendicular to the first direction.

5. The high-speed and high-energy-efficiency MTJ device of claim 2, wherein a second spin transfer torque, which is generated when a voltage is sequentially applied between the first terminal and the third terminal, is applied to the free layer whose magnetization direction was previously shifted due to a first spin transfer torque generated when a voltage is applied between the second terminal and the third terminal so that the magnetization direction of the free layer becomes an up or down direction.

6. The high-speed and high-energy-efficiency MTJ device of claim 2, wherein a second spin transfer torque, which is generated by a current flowing from the first terminal to the third terminal when a voltage is applied between the first terminal and the third terminal, is applied to the free layer whose magnetization direction is shifted due to a first spin transfer torque generated when a voltage is applied between the second terminal and the third terminal so that the magnetization direction of the free layer becomes an up direction.

7. The high-speed and high-energy-efficiency MTJ device of claim 2, wherein a second spin transfer torque, which is generated by a current flowing from the third terminal to the first terminal when a voltage is applied between the first terminal and the third terminal, is applied to the free layer whose magnetization direction is shifted due to a first spin transfer torque generated when a voltage is applied between the second terminal and the third terminal so that the magnetization direction of the free layer becomes a down direction.

8. The high-speed and high-energy-efficiency MTJ device of claim 1, wherein:
the magnetization direction of the auxiliary pinned layer is an in-plane direction parallel to a flat surface of a thin film; and
the magnetization direction of the main pinned layer is perpendicular to the flat surface of the thin film.

9. The high-speed and high-energy-efficiency MTJ device of claim 1, wherein a voltage applied between a second terminal and a third terminal and a voltage applied between a first terminal and the third terminal are supplied from different power sources.

10. A high-speed and high-energy-efficiency magnetic tunnel junction (MTJ) device comprising:
a first layer including a main pinned region in which a magnetization direction is determined to be a first direction, an auxiliary region in which a magnetization direction is determined to be a second direction intersecting the first direction, and an insulating region between the main pinned region and the auxiliary region;
an intermediate layer stacked on the first layer and including an oxide barrier; and
a second layer stacked on the intermediate layer and including a free region with stable magnetization states parallel and antiparallel to the first direction.

11. The high-speed and high-energy-efficiency MTJ device of claim 10, wherein areas occupied by the main pinned region and the auxiliary region are 20% and 70% of a total area of the first layer, respectively.

12. A method of operating a high-speed and high-energy-efficiency magnetic tunnel junction (MTJ) device, the method comprising:
sequentially applying a voltage to combinations of two terminals among a first terminal connected to a main pinned layer whose magnetization direction is determined to be a first direction, a second terminal connected to an auxiliary pinned layer whose magnetization direction is determined to be a direction perpendicular to the first direction, and a third terminal connected to a free layer having stable magnetization states parallel or antiparallel to the magnetization direction of the main pinned layer;
applying a voltage to a combination of the second terminal and the third terminal and shifting the magnetization direction of the free layer; and
applying a voltage to a combination of the first terminal and the third terminal and completing switching of the magnetization direction of the free layer.
